(19) United States
(12) Patent Application Publication
(10) Pub. No.: US 2025/0185417 A1
(43) Pub. Date: Jun. 5, 2025

(54) OPTOELECTRONIC COMPONENT AND METHOD FOR PRODUCING AN OPTOELECTRONIC COMPONENT

(71) Applicant: ams-OSRAM Internatonal GmbH, Regensburg (DE)

(72) Inventors: Andreas Lex, Zandt (DE); Adrian Stefan Avramescu, Regensburg (DE); Martin Hetzl, Painten (DE); Laura Kreiner, Regensburg (DE); Ingrid Koslow, Regensburg (DE)

(21) Appl. No.: 18/846,132

(22) PCT Filed: Mar. 20, 2023
(86) PCT No.: PCT/EP2023/057041

§ 371 Date: Sep. 11, 2024

(30) Foreign Application Priority Data
Mar. 21, 2022 (DE) 10 2022 106 583.9

(51) Int. Cl. H10H 20/813; H10H 20/01; H10H 20/819; H10H 20/821; H10H 20/825; H10H 29/01; H10H 29/14

(52) U.S. Cl. CPC H10H 20/8132; H10H 20/01335; H10H 20/819; H10H 20/821; H10H 20/825; H10H 29/011; H10H 29/142

(57) ABSTRACT

In an embodiment an optoelectronic component includes a plurality of active regions configured to produce electromagnetic radiation, wherein the active regions are laterally arranged next to each other and spaced from each other, wherein the plurality of active regions comprises at least one first-type active region and at least one second-type active region, which are based on the same semiconductor material system and have different bandgaps in order to produce different electromagnetic radiations, wherein the first-type active region is laterally surrounded by a first-type mask and the second-type active region is laterally surrounded by a second-type mask, wherein the masks are of different materials, and wherein the materials of the masks are selected from SiO₂, SiN, TiO, TiN, or Al₂O₃.

### CROSS-REFERENCE TO RELATED APPLICATIONS

This patent application is a national phase filing under section 371 of PCT/EP2023/057041, filed Mar. 20, 2023, which claims the priority of German patent application 102022106583.9, filed Mar. 21, 2022, each of which is incorporated herein by reference in its entirety.

### TECHNICAL FIELD

The present disclosure relates to an optoelectronic component and a method for producing an optoelectronic component.

### SUMMARY

Embodiments provide an improved optoelectronic component, e.g. an optoelectronic component with a compact design and/or with reliable operation. Further embodiments provide an improved method for producing an optoelectronic component, e.g. a particularly simple and efficient method.

Firstly, the optoelectronic component is specified.

According to at least one embodiment, the optoelectronic component comprises a plurality of active regions, also referred to as active layers. Each active region is configured for producing electromagnetic radiation. The active regions may be contiguous regions, e.g. without interruptions.

Each active region may comprise at least one p/n-junction and/or at least one quantum well structure, for instance in the form of a single quantum well or in the form of a multi quantum well. The active regions are configured to produce electromagnetic radiation due to the recombination of electrons and holes.

According to at least one embodiment, the active regions are laterally arranged next to each other and spaced from each other in lateral direction. Particularly, the active regions are spaced from each other pairwise. The region between each two active regions is, e.g., not provided for producing electromagnetic radiation. For example, during normal operation of the optoelectronic component, no electromagnetic radiation is produced in the region between the active regions.

A lateral direction is herein defined as a direction along the main extension plane of the optoelectronic component. The active regions may each extend parallel to the main extension plane of the optoelectronic component. That is, the active regions may extend in the lateral directions. For instance, the length and width of each active region, both measured in lateral directions, are larger than the respective thickness, measured perpendicularly to the main extension plane.

According to at least one embodiment, the plurality of active regions comprises at least one first-type active region and at least one second-type active region.

According to at least one embodiment, the first-type active region and the second-type active region are based on the same semiconductor material system. This particularly means that the components of the crystal lattice of both type active regions are the same. However, the composition, i.e. the concentrations of the different components, may differ.

For example, the semiconductor material system is a III-V compound semiconductor material system. The semiconductor material system is, for example, a nitride compound semiconductor material system, such as AlₙIn₁₋ₙ₋ₘGaₘN, or a phosphide compound semiconductor material system, such as AlₙIn₁₋ₙ₋ₘGaₘP, or an arsenide compound semiconductor material system, such as AlₙIn₁₋ₙ₋ₘGaₘAs or AlₙIn₁₋ₙ₋ₘGaₘAsP, where 0≤n≤1, 0≤m≤1, and m+n≤1, respectively. The active regions may have dopants as well as additional components. For simplicity, however, only the essential components of the crystal lattice, i.e. Al, As, Ga, In, N or P, are indicated, even if these may be partially replaced and/or supplemented by small amounts of additional substances. Preferably, the active regions are based on AlInGaN.

According to at least one embodiment, the first-type active region and the second-type active region, even though based on the same semiconductor material system, have different bandgaps in order to produce different electromagnetic radiations, i.e. electromagnetic radiations with different wavelength spectra.

The bandgaps of the active regions can be adjusted by the composition of the semiconductor material. For example, the concentrations of components of semiconductor material may be different in the first-type active region than in the second-type active region.

The bandgap of the first-type active region may differ from the bandgap of the second-type active region by at least 0.1 eV or at least 0.2 eV. For example, the electromagnetic radiations emitted by the first-type active region and the second-type active regions are each visible light. The color of the light produced in the first-type active region may be different than the color produced in the second-type active region. For example, the first-type active region produces blue light and the second-type active region produces green or red light.

Additionally to the first-type active region and the second-type active region, the plurality of active regions may also comprise at least one third-type active region. The third-type active region may also be based on the same semiconductor material system as the first-type and second-type active regions. The third-type active region may have a different bandgap than the first-type active region and than the second-type active region in order to produce a different radiation than the first-type active region and the second-type active region. For example, the third-type active region also produces visible light, but of a different color than the first-type active region and the second-type active regions.

By way of example, the first-type active region produces UV-radiation and/or blue light, the second-type active region produces yellow and/or green light and the third-type active region produces orange and/or red light and/or IR radiation.

In the following, mainly features for the first-type active region and the second-type active region are disclosed. However, corresponding features are also disclosed for the third-type active region. For example, disclosed differences between the second-type active region and the first-type active region may also be valid for the third-type active region with respect to the second-type active region and/or with respect to the first-type active region.

The plurality of active regions may comprise several first-type active regions and/or several second-type active regions and/or several third-type active regions. All features disclosed in connection with one first-type active region are also disclosed for all other first-type active regions. The same applies correspondingly for the second-type active regions and the third-type active regions.

There may also be further-type active regions, like one or more fourth-type active regions and so on. The features disclosed in connection with the first-type, second-type and third-type active regions correspondingly apply to the further-type active region(s), wherein the bandgap of the further type active region(s) may again differ from the other type active regions.

In at least one embodiment, the optoelectronic component comprises a plurality of active regions for producing electromagnetic radiation, wherein the active regions are laterally arranged next to each other and spaced from each other in lateral direction. The plurality of active regions comprises at least one first-type active region and at least one second-type active region which are based on the same semiconductor material system and which have different bandgaps in order to produce different electromagnetic radiations.

μLEDs are one approach to small displays, e.g. for AR/VR devices. μLEDs require small pixels of different emission wavelengths like red, green and blue. In solid-state LEDs and μLEDs, different materials systems are usually used for different color regimes. Blue to green light is mainly covered by AlInGaN, green to red by AlGaAsP or InAlGaP.

The inventors of the present invention had the idea to produce active regions producing different colors from the same semiconductor material system, e.g. AlInGaN. This is advantageous because the operation conditions (e.g. operation voltage, temperature dependence) of the different active regions are then comparable, which enables downsizing of the whole optoelectronic component and the use of a uniform fabrication process. Furthermore, the possibility of a transfer to 12″ Si substrates becomes possible. A single die transfer can be omitted in this case.

According to at least one embodiment, the first-type active region and the second-type active region are each assigned to an individual semiconductor structure by being grown on a top side of said semiconductor structure. The semiconductor structures may each be a protrusion protruding from a substrate, like a growth substrate, in a direction away from the substrate. The top side of a semiconductor structure may be the sides facing away from the substrate. The top side may be a plateau of the semiconductor structure. The semiconductor structure may each be doped, e.g. n-doped.

According to at least one embodiment, the geometry of the first-type semiconductor structure is different from the geometry of the second-type semiconductor structure. A first-type semiconductor structure is herein understood to be a semiconductor structure assigned to a first-type active region. Accordingly, a second-type semiconductor structure is assigned to a second-type active region.

The active regions may completely cover the top sides of the assigned semiconductor structures. The different-type semiconductor structures may be based on the same semiconductor material system. Even the composition of the semiconductor material of the different-type semiconductor structures may be the same. For example, they are made of GaN.

The fact that the first-type semiconductor structure and the second-type semiconductor structure have different geometries means that they are formed with different geometries in a predetermined manner. For example, the first-type semiconductor structure may have a different height and/or width than the second-type semiconductor structure, wherein the width is measured in lateral direction, e.g. at the top side, and the height is measured perpendicularly to the main extension plane of the optoelectronic component. For example, the first-type active region is then arranged on a different height than the second-type active region.

The geometry of the semiconductor structure may have a major impact on the growth/production of the active region thereon, particularly a major impact on the exact composition of the active region and, with this, a major impact on the resulting bandgap. As will be shown in the following, there are a few degrees of freedom in the geometry of the semiconductor structures for influencing the bandgap of the produced active region.

According to at least one embodiment, the first-type and second-type semiconductor structures each have, additional to the top side, at least one lateral side. The lateral side is the side of the semiconductor structure delimiting the semiconductor structure in lateral direction. The lateral side may run obliquely or perpendicularly to the top side of the semiconductor structure. Accordingly, an angle between the top side and the lateral side may be 90° or larger or smaller than 90°. Preferably, the angle between the lateral side and the top side is larger than 90°, e.g. between 100° and 150° inclusive.

According to at least one embodiment, the first-type semiconductor structure differs from the second-type semiconductor structure by one or more of: the area of the top side, the area-ratio between the top side and the lateral side, the angle between the top side and the lateral side.

When producing an active region on a semiconductor structure, the growth conditions, particularly the sticking properties of one or more components of the deposited starting material used for producing the active regions are different at the top side and at the lateral side. This is a consequence of the crystal lattice of the semiconductor structures. For example, some components or elements, respectively, of the deposited starting material may be repelled or less attracted by the lateral side than by the top side or vice versa. As a consequence of this, components of the deposited starting material may travel/diffuse from the lateral side to the top side or vice versa. Therefore, the geometrical form of the semiconductor structure on which the active region is produced indeed influences the composition of the resulting active region and, accordingly, the resulting bandgap.

According to at least one embodiment, the plurality of active regions comprises a plurality of first-type active regions and a plurality of second-type active regions. Each first-type active region may be grown on a first-type semiconductor structure and/or each second-type active region may be grown on a second-type semiconductor structure.

According to at least one embodiment, a plurality of first-type active regions is accumulated in at least one first-type cluster and a plurality of second-type active regions is accumulated in at least one second-type cluster. Within a first-type cluster, there are preferably only first-type active regions. Within a second-type cluster, there are preferably only second-type active regions. For example, each of the clusters comprises at least two or at least three active regions.

Within a cluster, the corresponding active regions may be distributed evenly and/or regularly. For example, the pitches between each two neighboring active regions are constant. Also the areas of the active regions may be the same for all active regions within a cluster.

In plan view of the main extension plane of the optoelectronic component, each cluster may be assigned a contiguous area without interruptions. An area of an active region is herein the area of the active region as seen in the plan view of the main extension plane. The pitch between two active regions is herein understood to be the distance between the centers of two neighboring active regions. For example, the area of each active region is at most 1000 μm² or at most 75 μm² and/or at least 0.5 μm² or at least 8 μm². The area of an active region may be the same as the area of the top side of the assigned semiconductor structure. The pitch between two active regions in each cluster may be at most 10 μm or at most 5 μm or at most 2 μm and/or at least 0.2 μm.

According to at least one embodiment, the first-type cluster is different from the second-type cluster by one or more of: the pitch between the active regions in the cluster, the areas of the active regions in the cluster. “The areas of the active regions” means that the area of each first-type active region in the first-type cluster is different than the area of each second-type active region in the second-type cluster. For example, the pitch values differ from each other by a factor of at least 1.2 or at least 1.5 or at least 2. The values for the areas may differ from each other by a factor of at least 1.2 or at least 1.5 or at least 2.

Similar to what has been explained before, the sticking properties of at least one component of the starting material deposited for producing the active regions may be different in the area of the active regions than in the area between the active regions. Consequently, some of the elements may travel towards the active regions or away from the active regions. Therefore, different pitches, i.e. different sizes of the areas between the active regions, and/or different areas of the active regions indeed result in different bandgaps of the active regions.

According to at least one embodiment, the first-type active region and the second-type active region are laterally surrounded by masks of different materials, particularly of different electrically isolating materials. The masks are, e.g., used during growth of the semiconductor material of the active regions in order to define the areas where the active regions are to be produced.

Also, mask materials may have different sticking conditions for the different components of the starting material deposited for producing the active regions. Therefore, some of the components of the deposited starting material may travel from the mask towards the adjacent active region or from the active regions towards the adjacent mask. Thus, the material of the mask laterally surrounding the active regions indeed influences the production of the active region and, with this, the bandgap of the active region.

According to at least one embodiment, the material of the masks are selected from: SiO₂, SiN, TiO, TiN, Al₂O₃. For example, the material is amorphous at least up to 1100° C.

According to at least one embodiment, the active regions are based on AlₙIn₁₋ₙ₋ₘGaₘN, where 0≤n≤1, 0≤m≤1, and m+n≤1.

According to at least one embodiment, the first-type active region and the second-type active region have different In-concentrations. For instance, the second-type active region has a greater In-concentration than the first-type active region. The third-type active region may have a greater In-concentration than the second-type active region. For example, the In-concentration in the second-type active region is at least 1.2 times the In-concentration in the first-type active region. The In-concentration in the third-type active region may be at least 1.2 times the In-concentration in the second-type active region. By way of example, the following applies: 0.1≤1−n−m≤0.2 in the first-type active region, 0.2≤1−n−m≤0.35 in the second-type active region and/or 0.35≤1−n−m≤0.5 in the third-type active region.

According to at least one embodiment, the semiconductor structures are based on AlₙIn₁₋ₙ₋ₘGaₘN where 0≤n≤1, 0≤m≤1, and m+n≤1. For example, the semiconductor structures comprises a plurality of layers, e.g. of InGaN and/or GaN and/or AlInGaN and/or AlGaN.

According to at least one embodiment, in each case the top side is a c-plane. The semiconductor structures may have a Wurtzite crystal structure.

According to at least one embodiment, the lateral side is in each case a semipolar plane.

Indium has a higher sticking probability on a c-plane than on a semipolar plane. Therefore, some of the In-atoms diffuse from the semipolar plane to the c-plane during growth of the semiconductor material of the active regions. By adjusting the geometry of the semiconductor structures, the In-concentration in the produced active region can be adjusted.

According to at least one embodiment, the active regions are elongated. This means that the active regions each have a length which is larger, e.g. by a factor of at least 5 or at least 10, than a width and a thickness of the active regions. For example, the active regions are formed as stripes. All active regions may have the same length.

According to at least one embodiment, the stripes each extend in a longitudinal direction. The longitudinal direction is, particularly, a lateral direction. For example, the stripes are all parallel to each other.

According to at least one embodiment, the stripes are laterally spaced from each other in a transverse direction. The transverse direction is a lateral direction perpendicular to the longitudinal direction. The widths of the active regions are measured in the transverse direction. For example, the widths of the individual active regions are at most 5 μm or at most 1 μm and/or at least 0.1 μm.

The semiconductor structures are preferably formed corresponding to the active regions. For example, the top sides of the semiconductor structures are also elongated, e.g. stripe-like, with the same lengths and widths as the active regions. The semiconductor structures may be formed as ribs or fins or walls. The semiconductor structures may each comprise two lateral sides delimiting the semiconductor structure in transversal direction.

According to at least one embodiment, the optoelectronic component is pixelated. This means that the optoelectronic component comprises a plurality of pixels, each of which can produce and/or emit electromagnetic radiation.

According to at least one embodiment, the first-type active region is assigned to a first-type pixel and the second-type active region is assigned to a second-type pixel. For example, each first-type pixel is assigned two or more first-type active regions and/or each second-type pixel is assigned two or more second-type active regions.

According to at least one embodiment, the pixels are individually and independently operable in order to emit electromagnetic radiation. In order to achieve this, the optoelectronic component may comprise contact elements, which can be independently and individually powered. The size of the contact elements may define the area in which active regions are supplied with electrons and/or holes in order to produce electromagnetic radiation.

For example, in plan view of the main extension plane of the optoelectronic component, each contact element defining a pixel, overlaps either only with first-type active regions or only with second-type active regions or only with third-type active regions.

The optoelectronic component may be a semiconductor chip, e.g. an LED-chip, such as a μLED-chip (also called μLED). The optoelectronic component may be used in an AR/VR device or a projector or in a headlight, e.g. of an automobile.

A μLED does not necessarily have to have a rectangular radiation emission surface. For example, a μLED has a radiation emission surface in which, in plan view of the layers of the layer stack, any lateral extent of the radiation emission surface is less than or equal to 100 μm or less than or equal to 70 μm. For example, in the case the μLED is a rectangular μLED, an edge length-especially in plan view of the layers of the layer stack—is smaller than or equal to 70 μm or smaller than or equal to 50 μm.

The μLED may be used in a display. The μLED forms a pixels or a subpixels, for example. Small pixel size and a high density with close distances make μLEDs suitable, among others, for small monolithic displays for AR applications, especially data glasses. Besides AR- or VR-application, other applications of μLEDs may the use thereof in data communication or pixelated lighting applications. Different ways of spelling μLED, e.g. micro-LED, μ-LED, μLED, u-LED or micro light emitting diode can be found in the literature.

Next, the method for producing an optoelectronic component is specified. The method may be used to produce the optoelectronic component according to any one of the embodiments disclosed herein. Therefore, all features disclosed in connection with the optoelectronic component are also disclosed for the method and vice versa.

According to at least one embodiment, the method comprises a step of producing at least one first-type active region. The first-type active region may be produced on a growth substrate, e.g. on semiconductor material already grown on the growth substrate. The growth substrate may be, e.g., a sapphire substrate or a GaN substrate. A main extension plane of the growth substrate may be parallel to a main extension plane of the whole optoelectronic component.

Producing the first-type active region comprises growing, particularly epitaxial growing, of semiconductor material. The production may done only by growing, whereby the geometrical form of the first-type active region forms automatically during growth. Alternatively, producing the first-type active region may comprise growing a semiconductor layer and then structuring, e.g. etching, the semiconductor layer to one or more first-type active regions. This structuring may also be done to define pixels of the optoelectronic component.

According to at least one embodiment, the method comprises a step of producing at least one second-type active region laterally beside and laterally spaced from the first-type active region. The second-type active region may be grown on the growth substrate, e.g. on semiconductor material already grown on the growth substrate.

The same as disclosed for producing the first-type active regions is accordingly also disclosed for producing the second-type active region.

According to at least one embodiment, a starting material deposited for producing the first-type active region is the same as the starting material for producing the second-type active region so that the first-type active region and the second-type active region are based on the same semiconductor material system. Particularly, the composition of the starting material is the same when producing the two active regions, i.e. the ratios of the different components in the starting material is the same. Also the growth conditions, like temperature and pressure, may be the same for producing the first-type and the second-type active regions.

According to at least one embodiment, a surface on which the starting material is deposited for producing the active regions is formed such that the first-type active region is produced with a different bandgap than the second-type active region. Particularly, the surface on which the starting material is deposited is formed such that, in different areas, at least one component of the starting material has different sticking properties.

As explained before, the surface, e.g. the material or the crystal orientation of the surface, may indeed have an impact on the sticking properties of different components of a starting material used for growing a semiconductor. By adjusting the surface in the area where the active regions are to be produced and/or by adjusting the surface beside the areas where the active regions are to be produced, the composition of the produced active regions can be adjusted.

In the step of producing the at least one first-type active region, a plurality of first-type active regions may be produced. Several or all of the first-type active regions of the optoelectronic component may be produced simultaneously. The same may be true for the second-type and/or the third-type active regions.

According to at least one embodiment, the method comprises a step of producing at least one first-type semiconductor structure, e.g. on the growth substrate. For example, a plurality of first-type semiconductor structures are produced simultaneously in this step.

According to at least one embodiment, the method comprises a step of producing at least one second-type semiconductor structure, e.g. on the growth substrate. In this step, a plurality of second-type semiconductor structures may be produced simultaneously.

Also third-type semiconductor structures may be produced, e.g. on the growth substrate.

The first-type and/or second-type and/or third-type semiconductor structures may be grown by using one or more masks. Alternatively, a semiconductor layer may be grown and the semiconductor structures may be formed out of the layer by structuring the layer.

According to at least one embodiment, the at least one first-type active region is grown on a top side of the at least one first-type semiconductor structure and the at least one second-type active region is grown on a top side of the at least one second-type semiconductor structure.

According to at least one embodiment, the geometry of the first-type semiconductor structure is different from the geometry of the second-type semiconductor structure. For example, the height of the first-type semiconductor structure is different from the height of the second-type semiconductor structure so that the assigned active regions are arranged on different height/levels. The height or level is particularly the height or level with respect to the growing direction.

According to at least one embodiment, the semiconductor structures each have, additional to the top side, at least one lateral side, e.g. two lateral sides.

According to at least one embodiment, for producing the first-type and the second-type active regions, the starting material is deposited on the top sides and the lateral sides of the semiconductor structures.

According to at least one embodiment, the sticking properties of at least one component of the deposited starting material are different on the top side than on the lateral side. For example, the top side is, in each case, a c-plane and the lateral side is, in each case, a semipolar plane.

According to at least one embodiment, the first-type semiconductor structure differs from the second-type semiconductor structure by one or more of: the area of the top side, the area-ratio between the top side and the lateral side, the angle between the top side and the lateral side.

According to at least one embodiment, a plurality of first-type active regions and a plurality of second-type active regions are produced such that a plurality of first-type active regions is accumulated in at least one first-type cluster and a plurality of second-type active regions is accumulated in at least one second-type cluster.

According to at least one embodiment, the first-type cluster is different from the second-type cluster by one or more of: the pitch between the active regions in the cluster, the area of the active regions in the cluster.

According to at least one embodiment, when producing the first-type and the second-type active regions, a different amount of starting material is deposited in the area between two adjacent, e.g. each two adjacent, first-type active regions of the first-type cluster than between two adjacent, e.g. each two adjacent, second-type active regions of the second-type cluster. For example, in case that the areas of the active regions are the same in the first-type and the second-type cluster, the different amount of deposited starting material in the areas in between the active regions may lead to different bandgaps in the first-type cluster than in the second-type cluster.

According to at least one embodiment, the method comprises a step in which at least one mask is formed on the growth substrate. The mask may be of an insulating material, e.g. amorphous material, like SiO₂, SiN, TiO, TiN, Al₂O₃.

According to at least one embodiment, at least one recess is formed in the mask defining an area for the production of an active region. Semiconductor material may be exposed in the recess. For example, the recess is a hole. The recess may define the geometry of a semiconductor structure and/or of an active region produced in the recess. The mask forms part of the surface on which the starting material for producing the active region(s) is deposited.

Within the one or more recesses, either an active region may be produced or, firstly, a semiconductor structure is produced, e.g. grown, and then an active region is produced, e.g. grown, on the semiconductor structure.

For example, the second-type active region(s) and/or the third-type active region(s) are each produced in the area of a recess in a mask. The first-type active region(s) may also each be produced in an area of a recess in a mask or may be produced without using a mask.

According to at least one embodiment, the sticking properties of at least one component of the deposited starting material are different on the mask than in the area of the recess. For example, the sticking probability of In on the mask is lower than in the area of the recess.

According to at least one embodiment, the first-type active region is produced in the area of a recess of a first-type mask. The first-type mask thereby forms part of the surface on which the starting material for producing the first-type active region is deposited.

According to at least one embodiment, the second-type active region is produced in the area of a recess of a second-type mask. The second-type mask thereby forms part of the surface on which the starting material for producing the second-type active region is deposited.

According to at least one embodiment, the sticking properties of at least one component of the starting material are different on the first-type mask than on the second-type-mask, e.g. such that the at least one component of the starting material is more repelled by one mask than by the other. As explained before, the more a component is repelled in the area adjacent to an active region, the higher the concentration of this component in the active region can be. Therefore, by using different masks around the areas for producing the first-type and the second-type active regions, different bandgaps of the first-type and second-type active regions can be realized.

According to at least one embodiment, the first-type active region and the second-type active region are based on AlₙIn₁₋ₙ₋ₘGaₘN, where 0≤n≤1, 0≤m≤1, and m+n≤1.

According to at least one embodiment, the surface on which the starting material is deposited is formed such that a different concentration of In is accumulated in the first-type active region than in the second-type active region. This results in different bandgaps of the first-type and the second-type active region.

According to at least one embodiment, the first-type active region is produced simultaneously with the second-type active region. Particularly growing of the semiconductor material of the active regions may be done simultaneously.

According to at least one embodiment, the first-type active region and the second-type active region are produced one after the other. For example the first-type active region is produced before the second-type active region.

### BRIEF DESCRIPTION OF THE DRAWINGS

Hereinafter, the optoelectronic component and the method for producing an optoelectronic component will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures. For the sake of clarity, elements might not appear with corresponding reference symbols in all figures.

FIGS. 1 to 10 show five different exemplary embodiments of the optoelectronic component in different views;

FIGS. 11 to 13 show a first exemplary embodiment of the method for producing an optoelectronic component;

FIGS. 14 to 19 show a second exemplary embodiment of the method for producing an optoelectronic component;

FIGS. 20 to 25 show a third exemplary embodiment of the method for producing an optoelectronic component; and

FIGS. 26 to 31 show a fourth exemplary embodiment of the method for producing an optoelectronic component.

### DETAILED DESCRIPTION OF ILLUSTRATIVE EMBODIMENTS

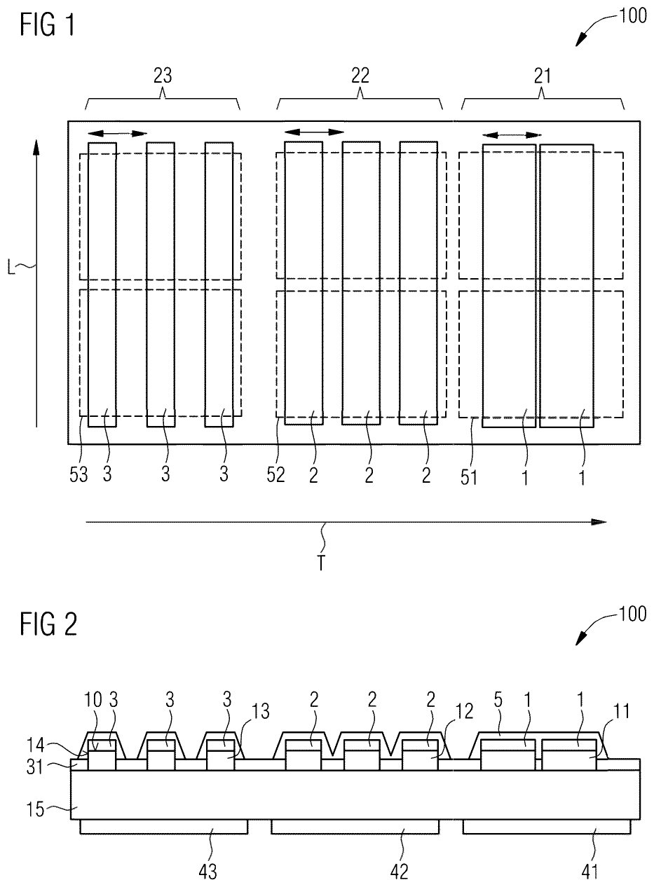

FIGS. 1 and 2 show a first exemplary embodiment of the optoelectronic component 100. FIG. 1 is a top view and FIG. 2 is a cross-sectional view. The optoelectronic component 100 may be a μLED, e.g. for AR/VR applications.

The optoelectronic component 100 comprises a substrate 15 on which a plurality of active regions 1, 2, 3 is located. The substrate 15 may be a growth substrate, e.g. sapphire. The active regions 1, 2, 3 are each grown on a top side 10 of a semiconductor structure 11, 12, 13. Each active region 1, 2, 3 is thereby assigned a semiconductor structure 11, 12, 13 on a one-to-one basis. For instance, the semiconductor structures 11, 12, 13 are grown on the substrate 15. The semiconductor structures 11, 12, 13 may be based on n-GaN. The active regions 1, 2, 3 are overgrown by a semiconductor layer 5, e.g., made of p-doped GaN.

The semiconductor structures 11, 12, 13 are formed as stripe-like ribs and, accordingly, the active regions 1, 2, 3 are formed as stripes (see FIG. 1). A mask 31 is located in the area laterally between the semiconductor structures 11, 12, 13. The mask 31 is used for defining and growing the semiconductor structures 11, 12, 13. The mask 31 is, e.g., of SiO₂.

The plurality of active regions 1, 2, 3 comprises first-type active regions 1, second-type active regions 2 and third-type active regions 3. The first-type active regions 1 are accumulated in a first-type cluster 21, the second-type active regions 2 are accumulated in a second-type cluster 22 and the third-type active regions 3 are accumulated in a third-type cluster 23. The stripe-like active regions 1, 2, 3 each extend in a longitudinal direction L and are arranged one after the other and spaced from each other in a transversal direction T.

As can be seen in FIG. 1, the optoelectronic component 100 comprises a plurality of pixels 51, 52, 53. Each pixel 51, 52, 53 is assigned several active regions of only one specific type. First-type pixels 51 are only assigned first-type active regions 1, second-type pixels 52 are only assigned second-type active regions 2 and third pixels 53 are only assigned third-type active regions 3. The pixels 51, 52, 53 are defined by contact elements 41, 42, 43 on a backside of the substrate 15 which can be independently and individually powered. Only those active regions overlapping with a powered contact element are supplied with electrons of holes and accordingly create electromagnetic radiation.

The first-type 1, second-type 2 and third-type 3 active regions are all based on the same semiconductor material system, e.g. AlInGaN. For example, the third-type active regions 3 have the greatest In-concentration, the first-type active regions 1 have the smallest In-concentration and the second-type active regions 2 have an In-concentration in-between. Accordingly, the first-type active regions 1 have the largest bandgap, the second-type active regions 2 have the second largest bandgap and the third-type active regions 3 have the smallest bandgap. All active regions of the same type may have the same bandgap and/or In-concentration.

In the present exemplary embodiment, the first-type active regions 1 produce blue light, the second-type active regions 2 produce green light and the third-type active regions 3 produce red light, for example. By powering the assigned electrodes 41, 42, 43, only blue light or only red light or only green light can be produced. Thus, a pixelated optoelectronic component is realized, which is for example suited for display applications in which all active regions are made from the same semiconductor material system. This is advantageous, since all active regions have similar operation properties. Also with respect to production, such an optoelectronic component is advantageous, as will be explained below.

The reason why the different-type active regions have different bandgaps and, therefore, produce different light, is herein mainly due to geometrical properties of the different active regions. As can be seen in FIGS. 1 and 2, the pitches between neighboring active regions, measured in transversal direction T, are the same in the first-type cluster 21, in the second-type cluster 22 and in the third-type cluster 23. However, the widths of the active regions 1, 2, 3, measured in transversal direction T, are different for the different-type active regions. The first-type active regions 1 have the largest widths, followed by the second-type active regions 2 and the third-type active regions 3 have the smallest widths.

When producing the active regions 1, 2, 3, there is a lower sticking probability for In, as one component of a starting material, on the mask 31 than on the semiconductor structures 11, 12, 13. Therefore, In-atoms travel from the area of the mask 31 to the area of the semiconductor structures. Due to the smaller width of the third-type-active regions 3 compared to the second-type 2 and first-type 1 active regions, the area of the exposed mask 31 is larger in the third-type cluster 23 than in the second-type cluster 22 and in the first-type cluster 21. Accordingly, a larger amount of In atoms travels into the third-type active regions 3 so that the In-concentration in the third-type active regions 3 becomes largest. The In-concentration in the second-type active regions 2 becomes larger than in the first-type active regions 1.

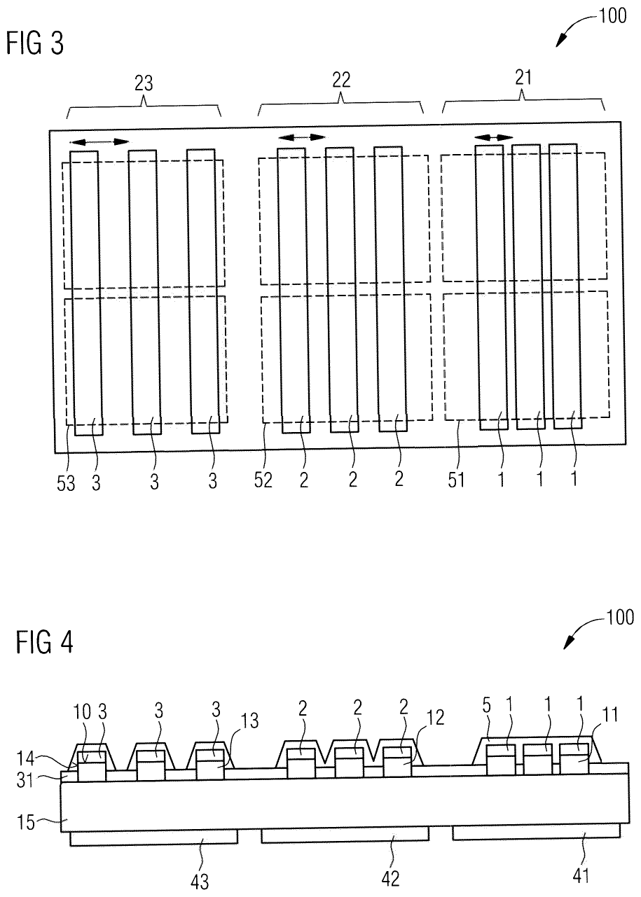

FIGS. 3 and 4 show a second exemplary embodiment of the optoelectronic component 100. This second exemplary embodiment is similar to the first exemplary embodiment. However, instead of all the clusters 21, 22, 23 having the same pitch between adjacent active regions, the active regions of each cluster have the same width. The pitch in the third-type cluster 23 is larger than in the second-type cluster 22 and the pitch in the second-type cluster 22 is larger than in the first-type cluster 21. Also in this configuration, a larger amount of In-atoms is deposited on the mask 31 in the area of the third-type cluster 23 than in the areas of the second-type cluster 22 and first-type 21 cluster so that, accordingly, the third-type active regions 3 are produced with the greatest In-concentration, followed by the second-type regions 2 and then by the first-type active regions 1.

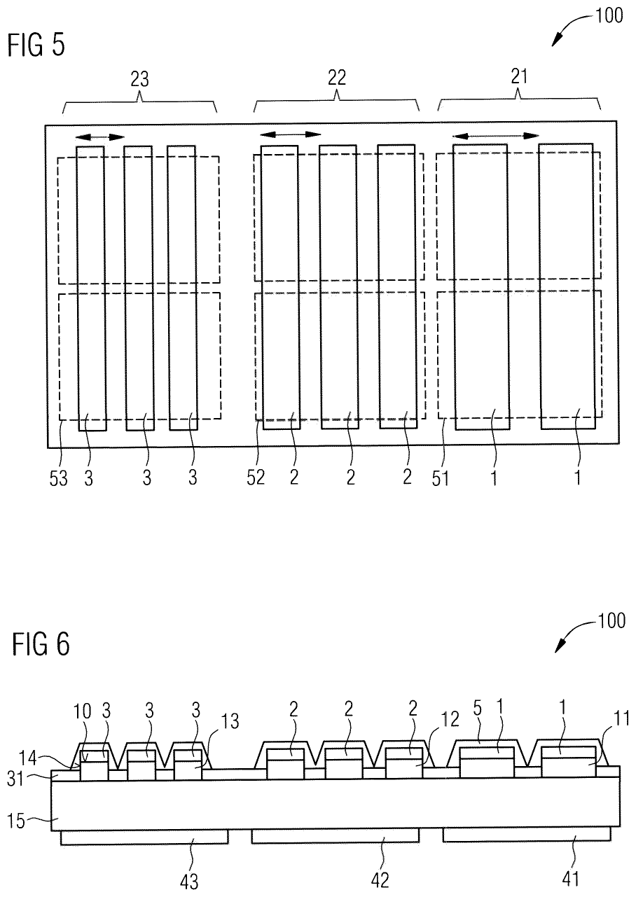

In the third exemplary embodiment of FIGS. 5 and 6, the pitch and the widths of the active regions are different in the different cluster types. Still, the configuration is such that the third-type active regions 3 are grown with the greatest In-concentration followed by the second-type active regions 2 and then by the first-type active regions 1. The third-type active regions 3 are most narrow which makes it possible that some of the Indium containing layers that are under the active regions 3 have the possibility to partially relax and thus enabling a higher intake of the Indium atoms. The increased In-concentration can be supported by large pitches in between the active regions 3.

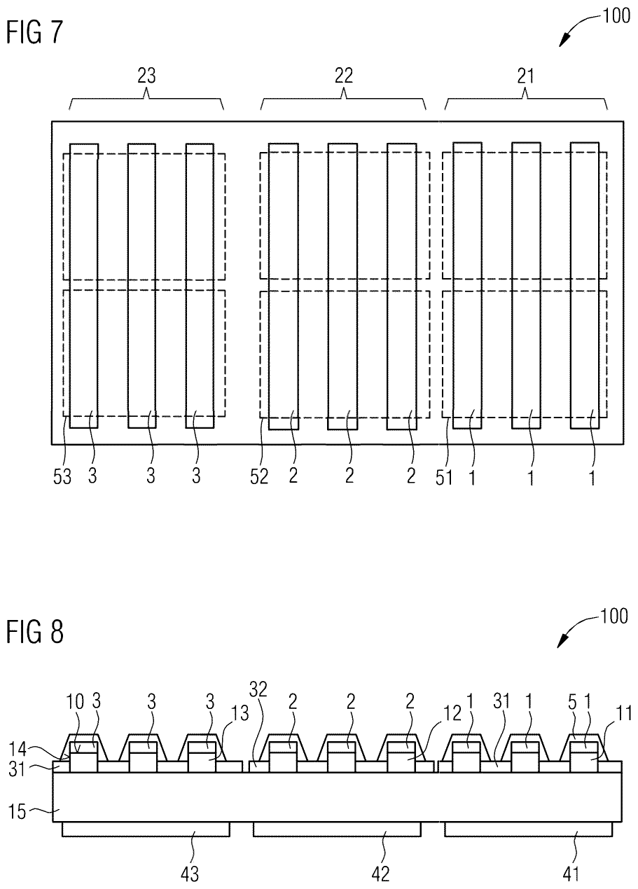

In the fourth exemplary embodiment of FIGS. 7 and 8, the pitches between the active regions and the widths of the active regions are the same in all clusters 21, 22, 23. However, as can be seen in FIG. 8, the masks laterally surrounding the active regions 1, 2, 3, are different in the different clusters 21, 22, 23. In the first-type cluster 21, a first-type mask 31 is used. This first-type mask 31 may be, e.g., of aluminium oxide. In the second-type cluster 22, a second-type mask 32 is used. This second-type mask 32 may be, e.g., of silicon nitride. In the third-type cluster 23, a third-type mask 33 is used, which may be, e.g., of silicon oxide.

The different masks 31, 32, 33 may result in different sticking probabilities for Indium so that different amounts of Indium travel to the active regions in the different clusters 21, 23, 23, and, accordingly, the different types of active regions 1, 2, 3 are produced with a different concentration of Indium.

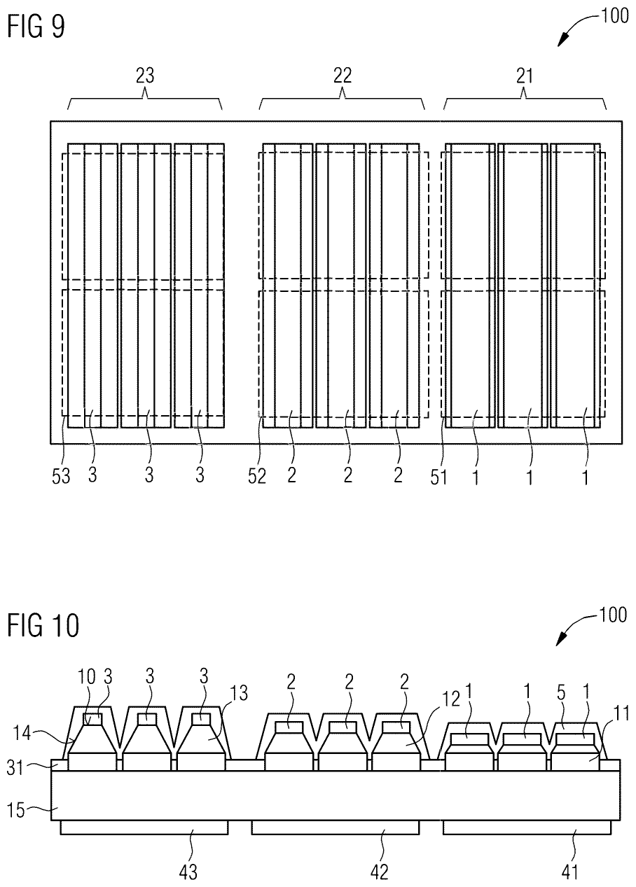

FIGS. 9 and 10 show a fifth exemplary embodiment of the optoelectronic component 100. Here, the semiconductor structures 11, 12, 13 in the different cluster types have different geometries. The semiconductor structures 11, 12, 13 have inclined lateral surfaces 14, which are semipolar surfaces. The top sides 10 of the semiconductor structures 11, 12, 13 are c-planes. During growth of the semiconductor material of the active regions 1, 2, 3, the sticking probability for Indium is greater on a c-plane than on a semipolar plane. Therefore, when producing the active regions 1, 2, 3, some of the In-atoms reaching a semipolar plane travel towards the adjacent c-plane.

Since the areas of the top sides 10, the areas of the lateral sides 14, particularly the area-ratios between the top sides 10 and the lateral sides 14, and/or the angle between the top sides 10 and the lateral sides 14, are different in the different cluster types, the active regions in the different cluster types are grown differently with different In-concentrations.

In FIGS. 9 and 10, particularly the area-ratio between the top side 10 and lateral side 14 is smallest for the third-type semiconductor structures 13 in the third-type cluster 23 so that the amount of Indium reaching the top side 10 and therefore accumulating in the active region is comparably large. In the first-type cluster 21, the area-ratio between the top sides 10 and the lateral sides 14 of the associated first-type semiconductor structures 11 is largest so that the first-type active regions 1 are produced with the smallest In-concentration.

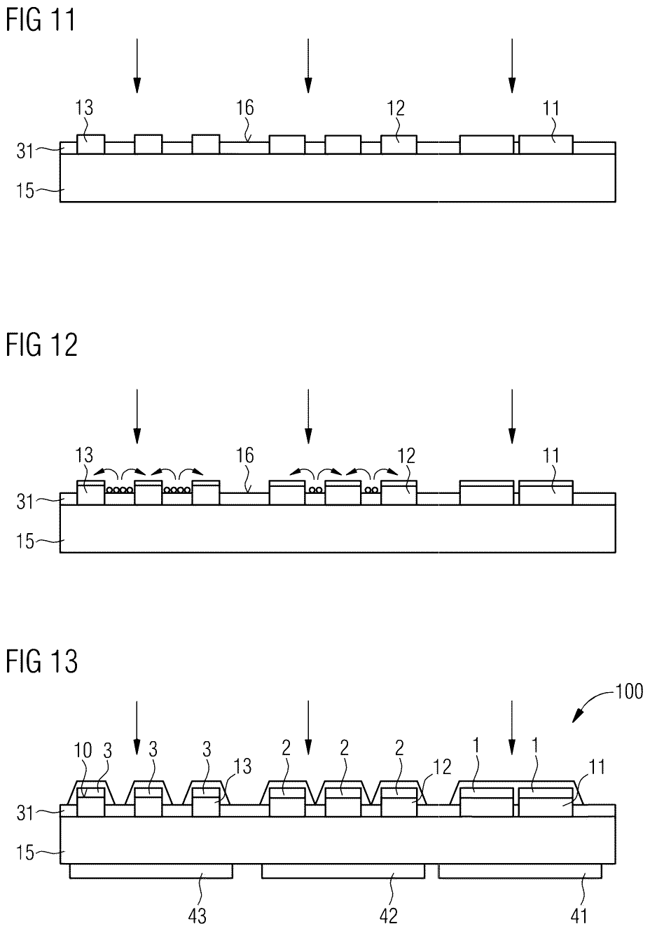

FIGS. 11 to 13 show a first exemplary embodiment of the method for producing an optoelectronic component in different positions. For example, the optoelectronic component 100 of FIGS. 1 and 2 is produced.

In FIG. 11, a growth substrate 15 is provided. A mask 31, e.g. of SiO₂, is applied to the top side of the growth substrate 15. The mask 31 comprises a plurality of recesses, in which semiconductor structures 11, 12, 13 are grown. The areas of the recesses and the pitches between the recesses define the areas and pitches of the semiconductor structures 11, 12, 13 and, accordingly, the areas and pitches of the resulting active regions.

In FIG. 12, a position is shown in which a starting material is deposited onto a surface 16 in order to grow the active regions. The surface 16 is partially formed by the mask 31 and partially formed by the different semiconductor structures 11, 12, 13. The deposited starting material comprises, e.g., In, Al, Ga and N in order to form AlInGaN. In the area of the semiconductor structures 11, 12, 13, the sticking probability for Indium is high. In the area formed by the mask 31, the sticking probability is lower and some of the In-atoms reaching the mask 31 then travel to the adjacent semiconductor structure and are incorporated into the growing active regions. This is indicated in FIG. 12.

Due to the different pitches and areas of the recesses in the mask 31, the amount of Indium traveling to an adjacent growing active region is varied. Third-type active regions 3, between which the area of the exposed mask 31 is largest and which have the smallest area, are formed with the highest concentration of Indium. First-type active regions 1 between which the area of the exposed mask 31 is smallest and which have the largest area are formed with the smallest concentration of Indium. The second-type active regions 2 are grown with an intermediate concentration of Indium. The different active regions 1, 2, 3 are grown simultaneously here.

FIG. 13 shows a position after the active regions 1, 2, 3 have been grown and after they have been overgrown by a semiconductor layer 5. On a bottom side, opposite the top side of the substrate 15, electrodes 41, 42, 43 have been applied defining different pixels.

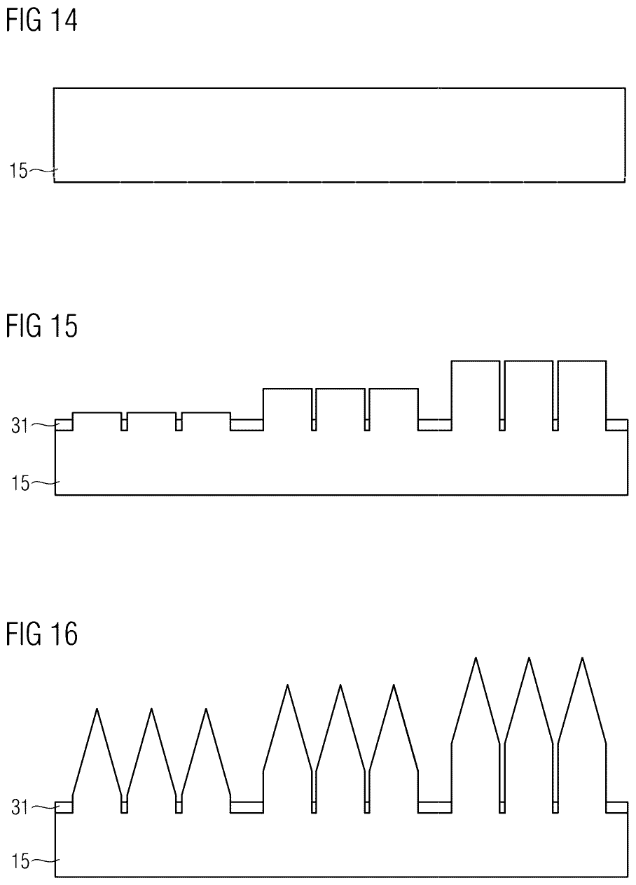

FIGS. 14 to 19 show a second exemplary embodiment of the method for producing an optoelectronic component in different positions.

In the position of FIG. 14, a growth substrate 15 is provided, e.g. of sapphire.

In FIG. 15, semiconductor structures are grown on the growth substrate 15 with the help of a mask 31. The semiconductor structures are grown with three different heights.

FIG. 16 shows a position, in which further semiconductor materials is grown on the semiconductor structures so that the resulting semiconductor structures taper in a direction away from the growth substrate 15.

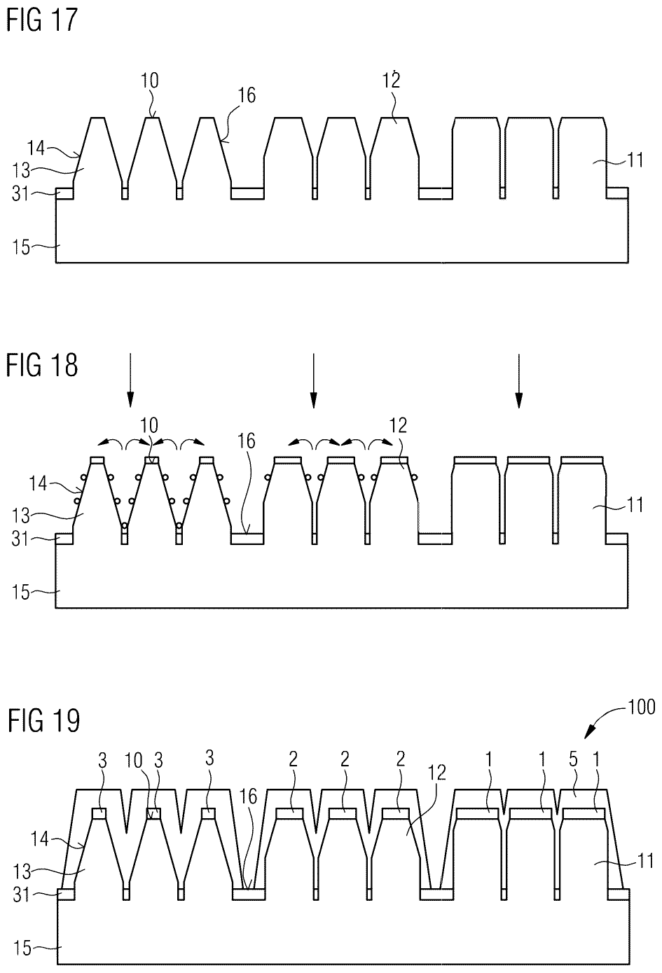

In FIG. 17, the semiconductor structures are planarized. As a consequence of the different heights of the initial semiconductor structures, the resulting flat top sides 10 of the semiconductor structures 11, 12, 13 in FIG. 17 have different areas. Furthermore, the resulting lateral sides 14 also have different areas. The top sides 10 are, e.g., c-planes and the inclined lateral sides 14 are, e.g., semipolar planes.

FIG. 18 shows a position in which a starting material for growing AlInGaN is deposited onto the exposed surface 16 in order to produce the active regions. The semipolar planes 14 have a lower sticking probability for Indium than the c-planes. Therefore, some of the In-atoms reaching the semipolar planes 14 travel towards the adjacent c-planes 10 and are then incorporated into the growing semiconductor material of the active region.

In FIG. 18, due to the different areas of the c-planes and the different areas of the semipolar planes 14, active regions with different concentrations of Indium are grown. Also here, the different active regions 1, 2, 3 are simultaneously grown.

FIG. 19 shows the resulting optoelectronic component 100 after the active regions 1, 2, 3 have been grown and after a semiconductor layer 5 has been grown over the active regions 1, 2, 3. The optoelectronic component 100 of FIG. 19 is similar to that of FIGS. 9 and 10.

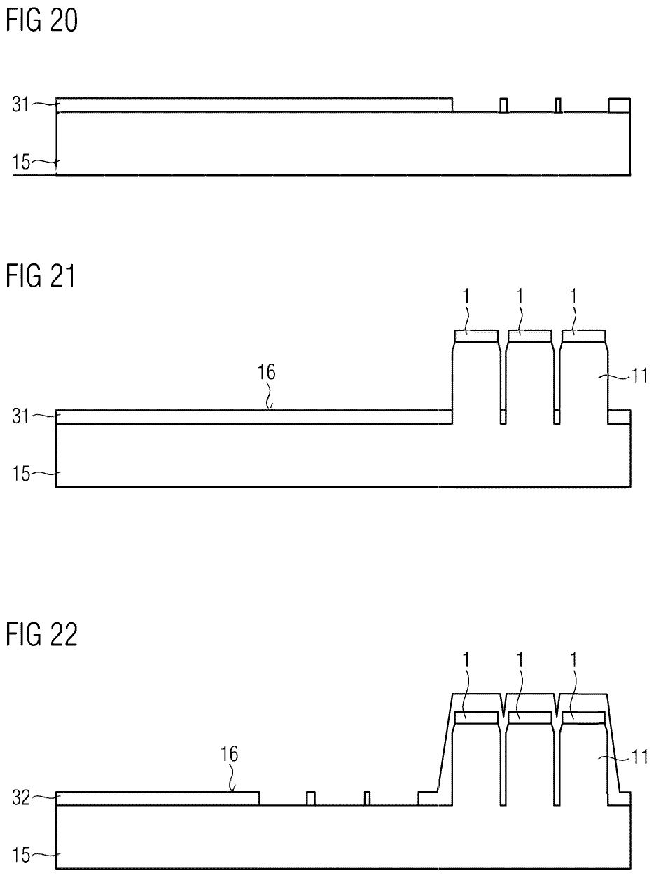

FIGS. 20 to 25 show a third exemplary embodiment of the method for producing an optoelectronic component. In FIG. 20, a growth substrate 15 is provided on top of which a first mask 31 is applied. The mask 31 comprises recesses for defining first-type active regions.

In the position shown in FIG. 21, semiconductor structures 11 are grown in the area of the recesses and, on top of these semiconductor structures 11, first-type active regions 1 are grown. For example, the first-type active regions 1 are made of AlInGaN.

FIG. 22 shows a position after the first mask 31 has been removed and a second mask 32 has been applied to the growth substrate 15 and over the first-type semiconductor structures 11 with the assigned first-type active regions 1. In an area laterally beside the first-type semiconductor structures 11, recesses are formed in the second mask 32 which define areas for second-type active regions.

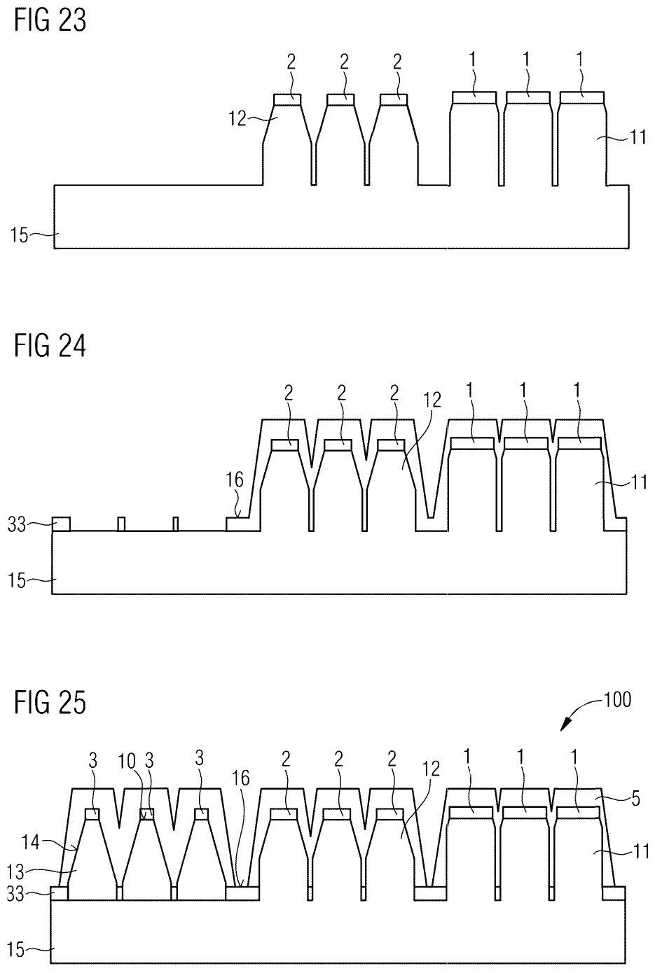

FIG. 23 shows a position after second-type semiconductor structures 22 and second-type active regions 2 have been grown. The second-type active regions 2 are based on the same semiconductor material system as the first-type active regions 1. The second-type semiconductor structures 22 have different geometries than the first-type semiconductor structures 11 due to which the second-type active regions 2 have a different In-concentration and a different bandgap. The reason for these different In-concentrations is the same as explained in connection with FIG. 18.

FIG. 24 shows a position after the second mask 32 has been removed and a third-mask 33 has been applied onto the growth substrate 15 and onto the already grown semiconductor structures 11, 12 with the assigned active regions 1, 2. Also in the third mask 33, recesses are formed defining where third-type active regions are to be produced.

FIG. 25 shows the result after third-type semiconductor structures 13 have been grown in the recesses of the third-mask 33 and third-type active regions 3 have been grown on the third-type semiconductor structures 13. The material system of the third-type active regions 3 is the same as of the second-type 2 and first-type 1 active regions. However, since the third-type semiconductor structures 13 have different geometries, particularly different areas of the top side 10 and of the lateral side 14, than the second-type 12 and first-type 11 semiconductor structures, the In-concentration in the third-type active regions 3 and accordingly, the bandgap in the third-type active regions 3 are different.

The method of this third exemplary embodiment differs from the previous exemplary embodiments, inter alia, in that the different-type active regions are grown one after the other.

In FIG. 25, the active regions 1, 2, 3 have been overgrown by a semiconductor layer 5.

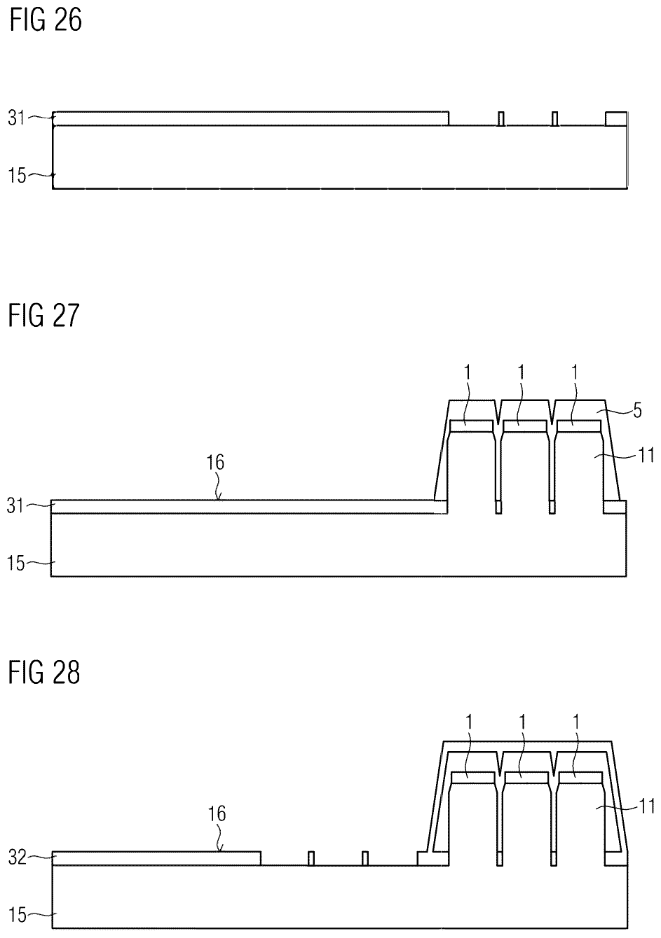

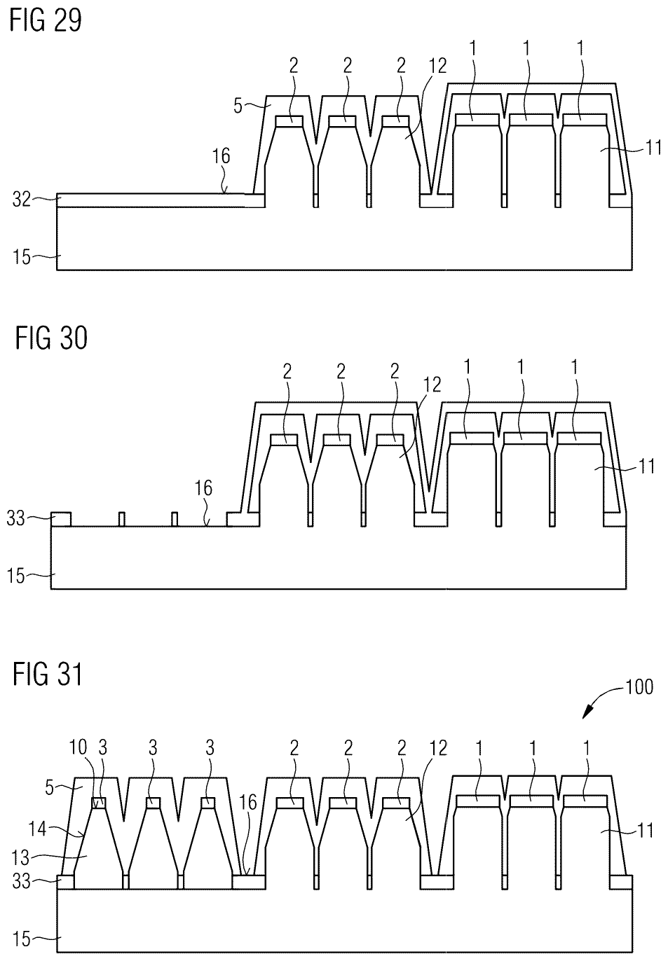

FIGS. 26 to 31 show a fourth exemplary embodiment of the method for producing an optoelectronic component. The method is similar to that of the third exemplary embodiment. In contrast to the third exemplary embodiment, the semiconductor layer 5 which is, e.g., p-GaN, is grown over one type active regions before a next type of active regions is produced.

The invention described herein is not limited by the description in conjunction with the exemplary embodiments. Rather, the invention comprises any new feature as well as any combination of features, particularly including any combination of features in the claims, even if said feature or said combination per se is not explicitly stated in the claims or exemplary embodiments.

1.-19. (canceled)

20. An optoelectronic component comprising:
a plurality of active regions configured to produce electromagnetic radiation,
wherein the active regions are laterally arranged next to each other and spaced from each other in lateral direction,
wherein the plurality of active regions comprises at least one first-type active region and at least one second-type active region, which are based on the same semiconductor material system and have different bandgaps in order to produce different electromagnetic radiations,
wherein the first-type active region is laterally surrounded by a first-type mask and the second-type active region is laterally surrounded by a second-type mask,
wherein the masks are of different materials, and
wherein the materials of the masks are selected from SiO₂, SiN, TiO, TiN, or Al₂O₃.

21. The optoelectronic component according to claim 20,
wherein each of the first-type active region and the second-type active region is assigned to an individual semiconductor structure by being grown on a top side of the semiconductor structure, and
wherein a geometry of a first-type semiconductor structure assigned to the first-type active region is different from a geometry of a second-type semiconductor structure being assigned to the second-type active region.

22. The optoelectronic component according to claim 21,
wherein each of the first-type semiconductor structure and the second-type semiconductor structure has, additional to a top side, at least one lateral side, and
wherein the first-type semiconductor structure differs from the second-type semiconductor structure by one or more of:
an area of the top side,
an area-ratio between the top side and the lateral side, or
an angle between the top side and the lateral side.

23. The optoelectronic component according to claim 22,
wherein the semiconductor structures are based on AlₙIn₁₋ₙ₋ₘGaₘN, where 0≤n≤1, 0≤m≤1, and m+n≤1,
wherein the top side is in each case a c-plane, and
wherein the lateral side is in each case a semipolar plane.

24. The optoelectronic component according to claim 20,
wherein the plurality of active regions comprises a plurality of first-type active regions and a plurality of second-type active regions,
wherein the plurality of first-type active regions is accumulated in at least one first-type cluster and the plurality of second-type active regions is accumulated in at least one second-type cluster, and
wherein the first-type cluster is different from the second-type cluster by one or more of:
a pitch between the active regions in the cluster, or
areas of the active regions in the cluster.

25. The optoelectronic component according to claim 20,
wherein the active regions are based on AlₙIn₁₋ₙ₋ₘGaₘN, where 0≤n≤1, 0≤m≤1, and m+n≤1, and
wherein the first-type active region and the second-type active region have different In-concentrations.

26. The optoelectronic component according to claim 20,
wherein the active regions are formed as stripes,
wherein each of the stripes extends in a longitudinal direction, and
wherein the stripes are laterally spaced from each other in a transversal direction.

27. The optoelectronic component according to claim 20,
wherein the optoelectronic component is pixelated,
wherein the first-type active region is assigned to a first-type pixel and the second-type active region is assigned to a second-type pixel, and
wherein the pixels are individually and independently operable in order to emit the electromagnetic radiation.

28. The optoelectronic component according to claim 20, wherein the optoelectronic component is a μLED.

29. A method for producing an optoelectronic component, the method comprising:
producing at least one first-type active region;
producing at least one second-type active region laterally beside and laterally spaced from the first-type active region,
wherein a starting material deposited for producing the first-type active region is the same as for producing the second-type active region so that the first-type active region and the second-type active region are based on the same semiconductor material system,
wherein a surface on which the starting material is deposited for producing the active regions is formed such that the first-type active region is produced with a different bandgap than the second-type active region; and
forming at least one mask on a growth substrate,
wherein at least one recess is formed in the mask defining an area for producing an active region,
wherein sticking properties of at least one component of the deposited starting material are different on the mask than in an area of the recess.

30. The method according to claim 29,
wherein the first-type active region is produced in the area of a recess of a first-type mask,
wherein the second-type active region is produced in the area of a recess of a second-type-mask, and
wherein the sticking properties of at least one component of the starting material are different on the first-type mask than on the second-type-mask.

31. The method according to claim 29, further comprising:
producing at least one first-type semiconductor structure; and
producing at least one second-type semiconductor structure,
wherein the at least one first-type active region is grown on a top side of the at least one first-type semiconductor structure,
wherein the at least one second-type active region is grown on a top side of the at least one second-type semiconductor structure, and
wherein a geometry of the first-type semiconductor structure is different from a geometry of the second-type semiconductor structure.

32. The method according to claim 31,
wherein each of the semiconductor structures has, additional to the top side, at least one lateral side,
wherein, for producing the first-type and the second-type active regions, the starting material is deposited on the top sides and the lateral sides of the semiconductor structures,
wherein the sticking properties of at least one component of the deposited starting material is different on the top side than on the lateral side, and
wherein the first-type semiconductor structure differs from the second-type semiconductor structure by one or more of:
an area of the top side,
an area-ratio between the top side and the lateral side, or
an angle between the top side and the lateral side.

33. The method according to claim 29,
wherein a plurality of first-type active regions and a plurality of second-type active regions are produced such that the plurality of first-type active regions is accumulated in at least one first-type cluster and the plurality of second-type active regions is accumulated in at least one second-type cluster, and
wherein the first-type cluster is different from the second-type cluster by one or more of:
a pitch between the active regions in the cluster, or
an area of the active regions in the cluster.

34. The method according to claim 29,
wherein the first-type active region and the second-type active region are based on AlₙIn₁₋ₙ₋ₘGaₘN, where 0≤n≤1, 0≤m≤1, and m+n≤1,
wherein the surface, on which the starting material is deposited, is formed such that a different concentration of Indium is accumulated in the first-type active region than in the second-type active region.

35. The method according to claim 29, wherein the first-type active region is produced simultaneously with the second-type active region.

36. The method according to claim 29, wherein the first-type active region and the second-type active region are produced one after the other.
